(19) United States
(12) Patent Application Publication
(10) Pub. No.: US 2024/0111647 A1
(43) Pub. Date: Apr. 4, 2024

(54) Battery Cell/Pack Testing Devices, Systems Including Such Devices, and Methods and Software for the Same

(71) Applicant: SES Holdings Pte. Ltd., Singapore (SG)

(72) Inventors: Younggyu Nam, Boston, MA (US); Yong Duan, Shanghai (CN); Yury Matulevich, Burlington, MA (US); Wentao Wang, Shanghai (CN); Qichao Hu, Arlington, MA (US)

(21) Appl. No.: 18/274,423

(22) PCT Filed: Feb. 2, 2022
(86) PCT No.: PCT/IB2022/050921

§ 371 Date: Jul. 26, 2023

Related U.S. Application Data
(60) Provisional application No. 63/145,053, filed on Feb. 3, 2021.

(51) Int. Cl. G06F 11/273; G01R 31/36; G01R 31/367; G01R 31/378; H01M 10/42; H01M 10/48

(52) U.S. Cl. CPC G06F 11/2733; G01R 31/3644; G01R 31/367; G01R 31/378; H01M 10/4285; H01M 10/48; H01M 10/482

(57) ABSTRACT

Testing devices for testing target test devices each composed of one or more battery cells, such as battery cells and battery packs. In some embodiments, a testing device may be considered self-contained in that it may include sufficient onboard systems and features to allow the testing device to conduct testing on one or more target test devices with minimal inputs, such as electrical power, higher-level instructions, and/or control inputs. In some embodiments, a testing device may include an explosion- and/or fire-proof or -resistant enclosure. In some embodiments, components of a testing device may be modularized for easy reconfiguring for different testing and/or different target test devices. In some embodiments, a plurality of testing devices can be controlled by a central testing controller. Related methods and systems are also disclosed.

### RELATED APPLICATION DATA

This application claims the benefit of priority of U.S. Provisional Patent Application Ser. No. 63/145,053, filed Feb. 3, 2021, and titled “BATTERY TESTING DEVICES, SYSTEMS INCLUDING SUCH DEVICES, AND METHODS AND SOFTWARE FOR THE SAME”, which is incorporated by reference herein in its entirety.

### FIELD OF THE INVENTION

The present invention generally relates to the field of battery testing. In particular, the present invention is directed to testing devices, systems including such devices, and methods and software for the same.

### BACKGROUND

New rechargeable-battery chemistries are under development that promise significantly increased capacity, reliability, and durability over current secondary-battery cell designs. The construction and design of the new battery cells provide different benefits, risks, and costs that must be explored to deliver a solution that satisfies specific operational requirements such as surge current capability, cycle life, high and low temperature operation, resistance to thermal runaway, self-extinguishing safety protocols, etc. Validation of the operational characteristics require very large amounts of testing due to the need to test multiple cell configurations, chemistries, and environmental conditions simultaneously, over long periods of time, with minimal human intervention, and with consistent application of test protocols. Conventional battery testing systems are not well suited to handling the large amount of testing needed for testing and optimizing new rechargeable battery chemistries of the next generation and beyond.

### SUMMARY OF THE DISCLOSURE

In one implementation, the present disclosure is directed to a testing device for testing a target test device composed of one or more battery cells. The testing device includes an enclosure designed, configured, and constructed to define a testing chamber that encloses the target test device and to contain or reduce the severity of an explosion of the target test device; a testing-device management system designed, configured, and constructed to be electrically connected to the target test device, to continually monitor one or more conditions of the target test device during testing, and to stop testing if the battery management system detects that any of the one or more conditions are out of an acceptable range, wherein the testing-device management system includes: circuitry for electrically interfacing with the target test device; one or more processors; memory operatively connected to the one or more processors; and machine-executable instructions stored in the memory and executable by the one or more processors to control operations of the testing-device management system.

In another implementation, the present disclosure is directed to a method of testing a target test device composed of one or more battery cells. The method includes executing, by a testing unit, a testing algorithm to conduct testing on the target test device based on a plurality of testing parameters; receiving from an external source one or more changed testing parameters; and executing, by the testing unit, the testing algorithm to conduct testing on the battery cell or battery pack using the one or more changed testing parameters.

In yet another implementation, the present disclosure is directed to a method of performing testing on a plurality of target test devices, wherein each of the target test devices is tested in a corresponding self-contained testing unit operatively connected by a communications link to a testing controller. The method includes determining testing parameters for each of the self-contained testing units; and sending the testing parameters to the self-contained testing units via the communications link.

### BRIEF DESCRIPTION OF THE DRAWINGS

For the purpose of illustration, the drawings show example aspects of one or more embodiments of this disclosure. However, it should be understood that the present disclosure is not limited to the precise arrangements and instrumentalities shown in the drawings, wherein:

FIG. 1A is a partial schematic diagram/partial block diagram of a self-contained testing device of the present disclosure for testing a battery cell and/or a battery pack;

FIG. 1B is a simplified cross-sectional view of the self-contained testing device of FIG. 1A having a cabinet-and-drawer arrangement;

FIG. 1C is a simplified cross-sectional view of the self-contained testing device of FIG. 1A having a vessel-and-closure arrangement;

FIG. 2 is a block diagram of a multi-testing-unit testing system of the present disclosure that includes a plurality of self-contained testing units communicatively connected to a central testing controller;

FIG. 3A is a side elevational/isometric view of an example instantiation of a self-contained testing unit made in accordance with the present disclosure, showing a side removed to reveal interior components;

FIG. 3B is a plan view of the example testing unit of FIG. 3A, showing the drawer in an open position;

FIG. 3C is an end elevational view of the example testing unit of FIG. 3A, showing components on the exterior of the drawer;

FIG. 4 is a flow diagram for an example method of testing a target test device utilizing a testing unit of the present disclosure; and

FIG. 5 is a flow diagram for an example method of testing a plurality of target test devices utilizing a multi-testing-unit system that includes a plurality of testing units of the present disclosure.

### DETAILED DESCRIPTION

In some aspects, the present disclosure is directed to battery testing devices. In some instantiations, these testing devices are also referred to as “testing units”. In some embodiments, a testing device of the present disclosure may be referred to as a “self-contained” testing device/unit in the sense that it can be configured to provide all of the hardware and software necessary to conduct cycle-life and other testing on a battery cell or a battery pack composed of one or more battery cells. As used herein, the term “battery cell” or “cell” is used to indicate the smallest operable element of an energy storage device that would typically be aggregated with other operable elements to form a battery pack. For example, differences between a battery cell and a battery pack include, but are not limited to: a battery cell is typically used together with other battery cells to deliver power in a consolidated fashion as part of a battery pack; a battery pack may include onboard electronics relating to battery management and/or power delivery, as well as an optional outer housing or intermediate container for incorporation into a larger or more complex device or machine. While a testing device/unit of the present disclosure is particularly useful for secondary battery cells and/or secondary battery packs, embodiments can be used for primary battery cells and/or primary battery packs. A battery testing device/unit of the present disclosure also need not be specific to any particular battery chemistry.

Embodiments of a testing device/unit of the present disclosure may be characterized as intelligent, self-contained battery testing units that can operate either in a standalone configuration or as part of a larger system of multiple testing units that are networked together in a multi-unit testing system and communicate, for example, with a remote testing controller, which may include testing controller software. It is noted that in this disclosure the term “central testing controller” is used for such a testing controller, with “central” relating to functional relationship to the multiple testing devices/units connected thereto.

As the testing protocol for a rechargeable battery cell may involve multiple charge/discharge cycles measured in the hundreds or thousands of cycles (weeks or months of time), a battery testing unit of the present disclosure may be designed to manage cell-data-collection events and safety protocols independent of (significant) human intervention. For example, embodiments of a testing unit of the present disclosure may constantly/continually/periodically check the operating conditions of the battery cell or battery pack under test and verify that the conditions are within allowable parameters. In the event that the testing unit detects an excursion outside the allowed limits, the testing unit may be configured to safely and definitively shut down the battery cell or battery pack to prevent damage and/or a safety issue. In some embodiments, supervisory control aspects of a testing unit of the present disclosure, which may be performed by a suitable testing device management system that is driven by software, are designed to be powered either by the cell under test or alternatively through a separate external power source, or both, for example in a manually or automatically switchable manner, depending on factors such as the testing conditions and the type of battery cell or battery pack under test, among others.

While embodiments of a testing unit of the present disclosure may normally be configured once at the beginning of a test routine via user input or testing-controller input, a supervisory control unit of the testing unit, which may be part of a testing device management system, can be designed and configured to accept updated or new operational parameters from a remote testing controller or other device, in real-time. This can allow for rapid dissemination of new configurations or safety protocol(s) across a fleet of testing units without requiring individual updating of each testing unit, thereby saving time and cost and improving the responsiveness to any pending safety issue.

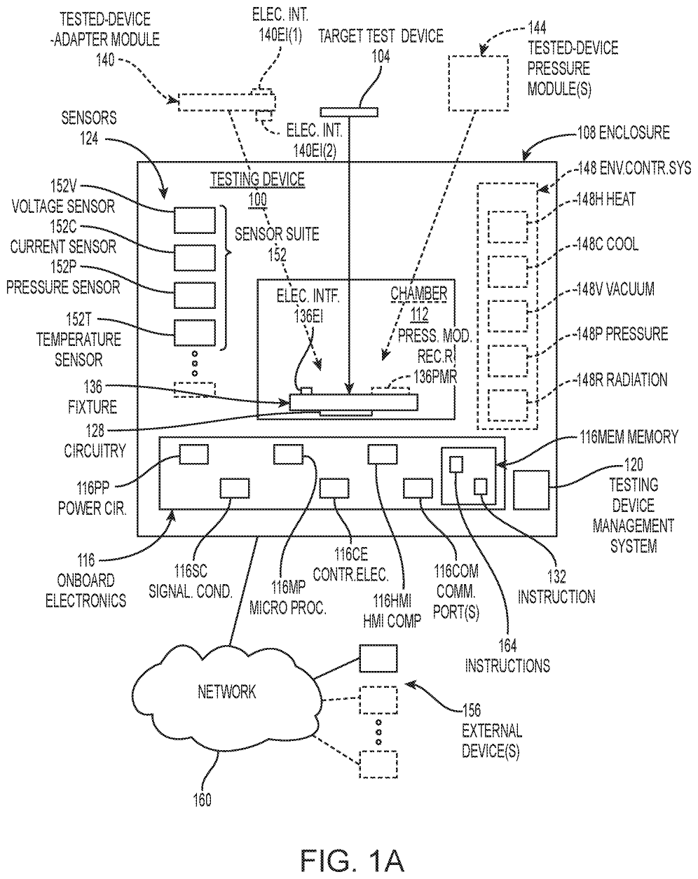

In some embodiments of a testing device of the present disclosure, such as a self-contained testing device, the testing device may be modularized to any of one or more various degrees of modularity to make the testing device readily adaptable to differing test subjects (e.g., differing battery cells and/or differing battery packs), differing testing regimes (e.g., differing pressure regime (no pressure, constant pressure, variable pressure, etc.), and/or differing data-collection requirements. Such modularity can make a testing device of the present disclosure economical. For example, for each new cell or battery-pack form factor, all that may be required is a new modular adapter customized to the new form factor. Such an adapter may have a customized cell or battery-pack electrical connector(s) on an electrical-input side and a standard electrical connector on an electrical output side that interfaces with an unchanging electrical connector on the testing device itself. Such an adapter may be customized one or more ways in addition to the electrical-connector customization, for example, the adapter may include a cradle or other holding arrangement customized to the cell or battery pack, and/or the adapter may include a customized sensor set and/or the adaptor may include a custom constant- or variable-pressure jig, among others. Further details regarding modularity and corresponding modules are described below in connection with FIG. 1A.

Referring now to the accompanying drawings, FIG. 1A illustrates an example testing device 100, which in this example is a self-contained testing unit that is capable of independent standalone operation. In other words, the testing device 100 of FIG. 1A is configured to perform one or more tests on a target test device 104 (e.g., a battery cell or a battery pack) and to be controlled, if desired, to perform such test(s) and shutdown testing as needed, without connection to or communication with any external device, such as an external testing controller. That said, in some embodiments, the testing device may be augmented to communicate with one or more offboard devices (see below) for any one or more of a variety of purposes, so as to be provided with testing parameters, be controlled by another device, such as a central testing controller, and communicating test data, among others, and any combination thereof.

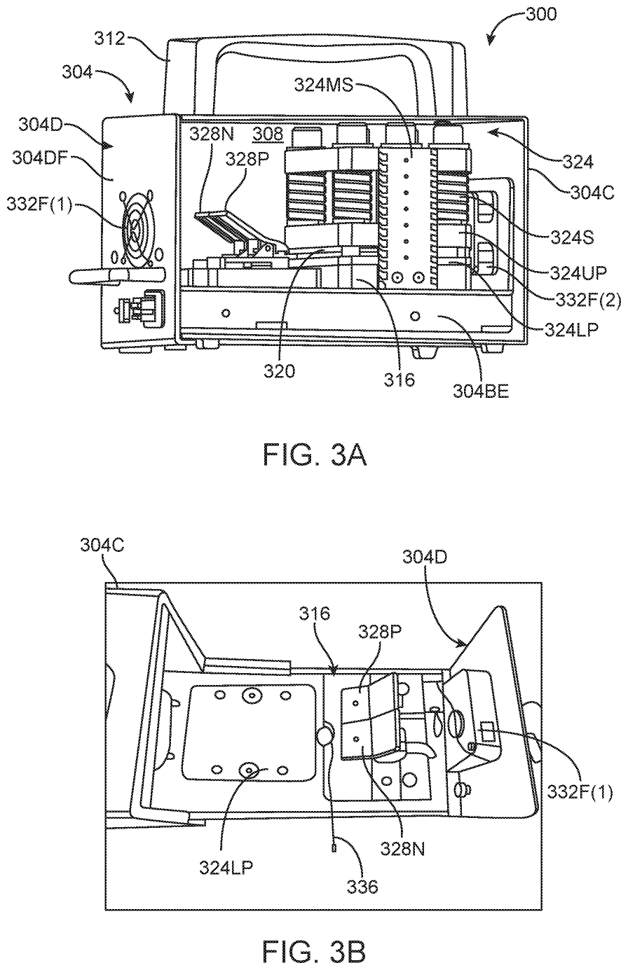

The testing device 100 includes an enclosure 108, for example, an explosion-proof or explosion-resistant and/or fire-proof or fire-resistant enclosure, that contains a testing chamber 112 for containing the target test device 104 during testing. The testing device 100 may also include onboard electronics 116 for performing all of the electronically based functions and providing all of the electronically based features of the testing device. In some embodiments, all of the onboard electronics 116 may be located within the enclosure 108 or may be otherwise engaged with the enclosure. Examples of electronics that can be included in the onboard electronics 116 include, but are not limited to, power-providing electronics 116PP (e.g., for charging of the target test device 104) and for powering onboard electronics and/or systems (e.g., actuators, heater(s), coolers, etc.), signal-conditioning electronics 116SC (e.g., for sensor signals), microprocessor(s) 116MP (e.g., microprocessor(s), etc.), memory 116MEM (e.g., onboard RANI and/or ROM, etc. (physical memory, not signals)), control electronics 116CE (e.g., for controlling any onboard heater(s), cooler(s), pressurizing device(s), etc.), human-machine interface(s) (HMI) component(s) 116HMI (e.g., graphical user interface (GUI) display(s), touchpad(s), etc.), and communications port(s) 116COM (e.g., wireless radio(s), etc.), among others, and any combination or subcombination thereof. Those skilled in the art will understand the electronics that need to be included in the onboard electronics 116 for any particular instantiation of the testing device 100, such that additional disclosure on the onboard electronics need not be elaborated upon further in this disclosure for those skilled in the art to make and use the testing device without undue experimentation. As noted above, the onboard electronics 116 may be powered by any suitable power source (not shown) internal and/or external to the testing device 100, including being powered solely by the target test device 104 itself. It is noted that in some embodiments, the amount of power required by the testing device 100 may be minimized so as to be powered by the target test device 104. In some embodiments, the testing device 100 may need to be connected to an offboard power source (not shown) in order to be fully operational. In some embodiments, some of the onboard electronics 116 may be powered by the target testing device 104, if additional power is needed, the testing device 100 may be provided with one or more auxiliary power inputs (see, e.g., power port 348 of FIG. 3C, which is a power port for powering fans 332F(1) and 332F(2) (FIG. 3A) aboard an example instantiation 300 of the testing unit 100).

In the embodiment of FIG. 1A, the testing device 100 may be considered to include a testing-device management system 120 that is designed, configured, and constructed 1) to be electrically connected to the target test device 104, 2) to continually monitor one or more conditions of the target test device during testing, 3) to stop testing if any of the one or more conditions are out of an acceptable range, 4) to control one or more environmental conditions (e.g., via environmental control system 148 (see below)), and 5) to communicate with one or more external devices, such as a testing controller (not shown) to, for example, send acquired testing data and/or receive testing parameters, etc., and any combination thereof, among other things. In some embodiments, the testing-device management system 120 may utilize and/or be considered to include the microprocessor(s) 116MP, onboard sensors 124 (e.g., voltage sensor(s), current sensor(s), temperature sensor(s), pressure sensor(s), radiation sensor(s), etc.), interface circuitry 128 for electrically interfacing with the target test device 104 and the sensors, and machine-executable instructions 132, 164 stored in the memory 116MEM, as may be present in the testing device 100 and/or active in a current testing protocol, or any portion or subset thereof, in order to carry out its functionality. As those skilled in the art will appreciate, the testing-device management system 120 need not be a standalone system independent of other systems and/or components of the testing device 100, but rather may utilize one or more of such other systems and/or components, or portion(s) thereof, to perform the necessary functionality. Likewise, any software of the testing-device management system 120 need not be embodied in a discrete software application, but rather may be implemented in another manner, such as in software modules, among other things.

In some embodiments, the testing device 100 may include a fixture 136 that receives or otherwise holds the target test device 104 and/or one or more optional swappable modules (see below) that can be used for effecting the testing and management of the target testing device. Depending on the overall configuration of the testing device 100, the fixture 136 may include an electrical interface 136EI (e.g., electrical contacts and/or cable connector) for electrically connecting target test device 104 to the testing-device management system 120 onboard the testing device. Depending on the design of the testing device, the fixture 136 may be as basic as a designated region within the testing chamber 112 on one or more structural components of the testing device, such as a bottom plate (not shown) and/or sidewall (not shown), while in other embodiments the fixture may take another form, such as a pedestal, wall bracket, etc., engaged (e.g., securingly) with one or more structural components of the testing device located within the testing chamber.

In some embodiments, the fixture 136 may be configured to be engaged by one or more swappable test-device-adapter modules 140, each configured to receive and hold a corresponding one of differing test devices (not shown, but, e.g., battery cells and/or battery packs of differing configurations). In such case, the electrical interface 136EI may be configured to be engaged by a first electrical interface 140EI(1) (e.g., electrical contacts and/or cable connector) on such test-device-adapter module(s) 140. Each test-device-adapter module 140 may have a second electrical interface 140EI(2) for electrically connecting the target test device 104 to the test-device-adapter module. In some embodiments, multiple electrical interfaces similar to electrical interface 136EI may be provided for differing target test devices 104 having differing electrical contact arrangements.

When provided, the fixture 136 may include an optional pressure-module receiver 136PMR for receiving any of one or more optional swappable test-device-pressure modules 144, each designed and configured for controlling pressure within, and/or affirmatively applying pressure to, the target test device 104 during testing. For some types of battery cells/battery packs, such as lithium-metal battery cells/battery packs, it can be desirable to subject the battery cell/battery pack to compressive pressure in the stacking direction of the various functional layers to suppress dendrite growth on the lithium anode(s) of the battery cell or battery pack. In some cases, testing of such battery cells/battery packs is desirable to be performed under a relatively constant pressure, while in other cases testing is desirable to be performed under variable pressure brought about by fixedly constraining the battery cell/battery pack from expansion in the stacking direction. In some embodiments, a testing device kit may include two types of swappable test-device-pressure modules 144 that can be swapped out for one another or not present at all, depending on the testing that the testing device 100 is performing at the time. For example, one of the test-device-pressure modules 144 may be a constant-pressure module for applying constant pressure in the cell stacking direction, and the other pressure module may be a constant-gap pressure module that provides a fixed-width gap for constraining the battery cell/battery pack in the cell stacking direction. Not illustrated, but would be understood by those skilled in the art, are any connections (e.g., electrical, hydraulic, etc.) needed to functionally connect the test-device-pressure module 144 used to the testing device 100. In some embodiments, the functionalities of both a test-device-pressure module 144 and a test-device-adapter module 140 may be combined into a single swappable module. In some embodiments, each test-device-pressure module 144 may be swappably engaged with the test-device-adapter module 140 to function as a monolithic unit with one another. This is the example depicted in FIG. 1A. However, in other embodiments, when both a test-device-pressure module 144 and a test-device-adapter module 140 are provided, they may be independently engageable with the test fixture 136. In some embodiments, any optional test-device-pressure module 144 may be substituted with either a permanently installed pressurizing apparatus or a removable—but not modularized—pressurizing apparatus.

In some embodiments, the testing device 100 includes an environment-control system 148 that is configured to be operated to provide one or more environmental conditions that subject the target test device 104 to one or more conditions (heat, cold, low ambient pressure, high ambient pressure), for example, to simulate and/or exceed the condition(s) that the type of target test device is or is designed to endure during use. The environment-control system 148 may include any one or more of the following: a heating system 148H, a cooling system 148C, a vacuum system 148V, a pressure (ambient) system 148P, and a radiation system 148R (e.g., radio frequency, microwave, x-ray, etc.), among others. Example heating systems that can be used for heating system 148H include, but are not limited to, resistance-type heating systems, thermoelectric-type heating systems, radiant-type heating systems, and convection-type heating systems, among others, and any combination thereof. Example cooling systems that can be used for cooling system 148C include, but are not limited to, fan-type cooling systems, heat-sink-type cooling systems, thermoelectric-type cooling systems, refrigerant-based cooling systems, and other circulating-fluid-type cooling systems, among others, and any combination thereof. Regardless of the type(s) of heating and/or cooling system(s) utilize, they may be under the control of the testing-device management system 120.

The testing device 100 may include a device-sensor suite 152 that includes a set of sensors for sensing various conditions of the targeted test device 104. For example, the device-sensor suite 152 may include a voltage sensor 152V, a current sensor 152C, a temperature sensor 152T, and a pressure sensor 152P, among others. Depending on the configuration of the testing device 100, the sensor suite 152 may be partially or fully integrated into the testing device or partially or fully integrated into another component, such as a test-device-adaptor module 140. In some embodiments, such as embodiments for testing a battery pack, the testing device 100 may utilize one or more sensors/sensor systems (not shown) located onboard the battery pack. Those skilled in the art will be familiar with sensors needed for the device-sensor suite 152 and how to select, deploy, and/or use such sensors.

As alluded to above, some embodiments may include one or more HMI components 116HMI, for example a graphical UI (GUI), that, among other things, may allow a user to set parameters of the testing device 100, including setting one or more parameters for configuring the testing device as a stand-alone testing device or as a networked testing device where it would be one of multiple testing devices, as well as testing parameters for carrying out the desired testing. As described below, in some embodiments a network of multiple self-contained testing devices can be controlled via a common, or “central,” testing controller.

As also alluded to above, in addition or alternatively to the onboard HMI component(s) 116HMI, the testing device 100 may include one or more communications ports 116COM for communicating with one or more external devices 156 and/or a network 160 for any one or more of a variety of purposes. For example, a communications port 116COM may allow the external device 156 to communicate with the testing-device management system 120 to configure the testing device 100, to provide testing parameters to the testing device, and to receive testing data from the testing device, among other things. Each communications port 116COM may be wired or wireless, depending on the desired manner(s) in which the testing device is desired to be configured and used. Examples of wired communications ports suitable for use as a communications port 116COM include various standardized and proprietary serial or parallel data communications ports, among others. Examples of wireless communications ports suitable for use as a communications port 116COM include those that use any one or more of various wireless personal-area, local-area, and wide-area communications protocols/standards using, for example, one or more standards established under IEEE 802.11, IEEE 802.15, Long Term Evolution (LTE), GSM/EDGE, UMTS/HSPA, and CDMA2000, among others, and any combination thereof. Generally, there are no limitations on the type(s) of wireless and wired communications ports that may be used by the testing device.

As noted above, the testing device 100 will typically include one or more microprocessors 116MP, memory 116MEM, and one or more machine-executable instruction sets for carrying out some, most, or all of the automated or other functionalities of the testing device, such as machine executable instructions 132 for controlling functionalities provided by the testing-device management system 120, among others. Examples of other machine-executable instructions sets include machine-executable instructions 132 for setting up operating parameters for the testing device 100, processing data from the device-sensor suite 152, controlling operating parameters of the environment-control system 148, and controlling communications via the communications port(s) 116COM. Those skilled in the arts of hardware and software and integration thereof will readily understand how to instantiate computer-controlled versions of a testing device of the present disclosure, such as the testing device 100 of FIG. 1A, with an understanding of the functionalities of the testing device at issue, such that details and examples of such hardware and software are not needed herein for those skilled in the art to implement the present inventions to their broadest scopes.

Referring to FIG. 1B, in one example the enclosure 108 may generally be considered to include a cabinet 108C and a drawer 108D movably engaged with the cabinet so as to be movable as indicated by double-headed straight arrow 168. In this embodiment, a portion of the drawer 108D and portions of the cabinet 108C together define the testing chamber 112 of the testing device 100, and the drawer provides access to the testing chamber to allow a user to install and remove the target test device 104 into and from the testing chamber. In this embodiment of FIG. 1B, the cabinet 108C includes an electronics compartment 108EC in a rear portion of the cabinet that contains some or all of the electronics (not shown, but see examples shown in FIG. 1A) that are part of the testing device 100. In some embodiments, a partition 108P separating the testing chamber 112 and the electronics compartment 108EC may be robust to the extent of protecting the electronics in the electronics compartment from damage in the event of an explosion or other adverse catastrophic event with the target test device 104. In other embodiments, the electronics compartment 108EC may be located elsewhere within the enclosure 108, such as beneath, aside, or above the testing chamber 112, or in one or more portions of the drawer 108D, among other locations. Some embodiments may include a plurality of electronics compartments (not shown) at multiple various locations within the enclosure 108 in any combination of above, below, aside, behind the testing chamber 112, and/or in one or more portions of the drawer 108D. In some embodiments, the drawer 108D of FIG. 1B may include the fixture 136 so that the fixture moves with the drawer for easy access to the fixture. As discussed above, the fixture 136 may be configured in any one or more of a variety of ways, including being adapted to receive various testing-device-adaptor modules 140 (FIG. 1A) and test-device-pressure modules 144 (FIG. 1A), among other things.

FIG. 1C illustrates another example configuration of the enclosure 108 and the testing device 100 generally. In this configuration, the testing device 100 may include a vessel 108V (box or other shape) having a securable (re)movable closure 108MC (e.g., a door, hatch, etc.) for accessing the testing chamber 112 within the testing device. In the example shown, the (re)movable closure 108MC is a door-type closure that is hingedly secured to the vessel 108V to allow the (re)movable closure to be swung open and closed, as indicated by double-headed curved arrow 172. In this example, the (re)movable closure 108MC includes a securement mechanism 108MC(1) that allows a user to securely close the testing chamber 112. In some embodiments, the (re)movable closure 108MC can hermetically seal the testing chamber. Depending on the type of (re)movable closure 108MC used, it may be moveable relative to the vessel 108V in any suitable manner, such as hingedly (as in the current example), slidably, unattachably (after releasing the securement mechanism 108MC(1), among others.

In this embodiment of FIG. 1C, the vessel 108V includes an electronics compartment 108EC′ in a bottom portion of the cabinet that contains some or all of the electronics (not shown, but see examples shown in FIG. 1A) that are part of the testing device 100. In some embodiments, a partition 108P′ separating the testing chamber 112 and the electronics compartment 108EC′ may be robust to the extent of protecting the electronics in the electronics compartment from damage in the event of an explosion or other adverse catastrophic event with the target test device 104. In other embodiments, the electronics compartment 108EC′ may be located elsewhere within the enclosure 108, such as beneath, aside, or above the testing chamber 112. Some embodiments may include a plurality of electronics compartments (not shown) at multiple various locations within the enclosure 108 in any combination of above, below, aside, and/or behind the testing chamber 112. The testing chamber 112 of FIG. 1C may contain the fixture 136, which may be configured in any one or more of a variety of ways, including being adapted to receive various testing-device-adaptor modules 140 (FIG. 1A) and test-device-pressure modules 144 (FIG. 1A), among other things.

It is noted that while the testing device 100 of FIG. 1A is completely self-contained in the sense of independent operation and independent control noted above, other embodiments of a testing device of the present disclosure can have less than the full integration required for self-contained status. For example, some embodiments of the testing device 100 may not include any HMI components 116HMI, but rather require communicating with an external device, such as external device 156 that control aspects of the operation of the testing device, such as starting and stopping testing and configuring a test protocol. It is also noted that the testing device 100 of FIG. 1A is configured as a standalone self-contained testing device (though it can be controlled by and/or communicate with an external device 156 (see below), other embodiments may be configured to be self-contained but part of a multi-testing-device assembly having multiple same or similar testing units integrated into a unitary multi-testing-chamber piece of equipment. In such embodiments, each of the testing devices itself may be modular and removable. For example, if one of the testing devices is damaged, such as by an exploded or leaked cell or battery pack, the damaged testing device can be removed and replaced, for example, without disturbing any surrounding/adjacent undamaged testing device(s). It is further noted that while the testing device 100 of FIG. 1A is configured for testing a single target test device 104, the testing device 100 may be configured to test multiple target test devices, for example, either all contained in a single testing chamber 112 or contained in corresponding respective separate testing chambers, or a combination of the two. If multiple testing chambers are provided, they may be all controlled by software and operating electronics common to them all. Those skilled in the art will readily understand the variation of configurations that are possible using aspects of the present disclosure.

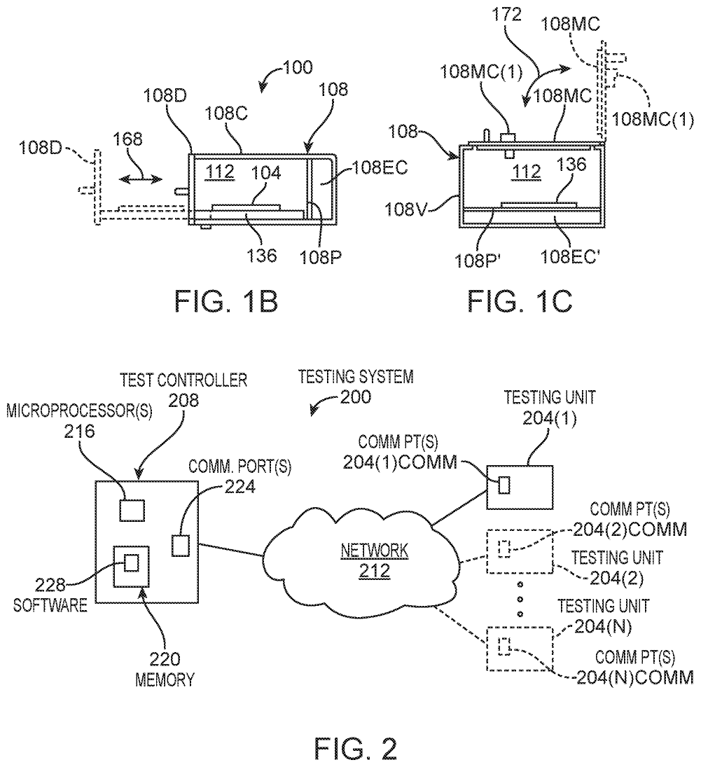

In some aspects, the present disclosure is directed to a testing system that comprises a plurality of self-contained testing units, such as multiple ones of the testing devices 100 described above, and a centralized testing controller. An example multi-testing-unit testing system 200 having such a configuration is shown in FIG. 2. Referring now to FIG. 2, the multi-testing-unit testing system 200 illustrated includes a plurality of testing units 204(1) to 204(N) and a testing controller 208, and the plurality of testing units and the testing controller may be in data communication with one another via a suitable data network 212. The data network 212 may be composed of any local-area network, wide-area network, or global network, or any combination thereof, suitable for the particular application at issue. Those skilled in the art understand the ubiquity and types of data networks and their interconnectivity and attendant communications protocols such that it is not necessary to describe the data network 212 in any detail other than indicating that the data network from the necessary two-way communications paths between and/or among the testing units 204(1) to 204(N) and the central controller 208 for those skilled in the art to be able to implement the present inventions and features disclosed herein to their fullest scopes.

Each testing unit 204(1) to 204(N) may be the same as or similar to any of the testing devices that can be made in accordance with the descriptions of the testing device 100 of the accompanying FIGS. 1A through 1C. Each testing unit 204(1) to 204(N) may be configured according to whatever type of target test device(s) is/are being tested in that testing unit. In some situations, the target test devices in all of the testing units 204(1) to 204(N) may be of the same type, for example, when multiple copies of the same design are being tested. In other situations, the target test devices may differ among the plurality of testing units 204(1) to 204(N). In either situation, the testing performed by the testing units 204(1) to 204(N) may be the same across all of the testing units or it may differ among the testing units, for example, by individual testing unit or by subgroups of testing units. Because each testing unit 204(1) to 204(N) can be configured individually to perform any of a wide variety of tests, under a wide variety of test conditions, and/or on a variety of sizes, types, and configurations of target test devices, setting-up the multi-testing-unit testing system 200 is a straightforward matter.

For example, setting up the multi-testing-unit testing system 200 may include, for each of the multiple testing units 204(1) to 204(N), any one or more of the following tasks: placing the testing unit in data communications with the testing controller 208; entering, setting, and/or selecting a testing protocol; installing one or more target test devices into the testing unit; selecting and installing an appropriate test-device-adapter module (e.g., one of the test-device-adapter modules 140 of FIG. 1A); and selecting and installing an appropriate test-device-pressure module (e.g., one of the test-device-pressure modules 144 of FIG. 1A); and securely closing the testing unit; among other things. As those skilled in the art will appreciate, the entering, setting, and/or selecting the testing protocol may be performed on each of the multiple testing units 204(1) to 204(N) (e.g., via one or more HMI components, such as one or more HMI components the same as or similar to the HMI components 116HMI of FIG. 1A), via the testing controller 208, and/or another device, such as a smartphone, laptop computer, tablet computer, a web server, etc.

The testing controller 208 may include one or more microprocessors 216, memory 220, and one or more communications ports 224 that allow it to be in operative communication with each of the plurality of testing units 204(1) to 204(N) via the network 212. The testing controller 208 may be embodied in any suitable hardware, such as a laptop computer, a tablet computer, a desktop computer, an application specific device, a web server, a smartphone, or any suitable combination thereof, among other hardware. In some embodiments, the testing controller 208 may control the overall operation of each of the testing units 204(1) to 204(N) and collects test data from each of the testing units. Each communications port 224 may be a wired or wireless communications system or device that communicates via one or more communications ports 204(1)COM to 204(N)COM aboard each of the testing units 204(1) to 204(N). Control by the testing controller 208 of each of the testing units 204(1) to 204(N) may include controlling a testing protocol for that testing unit based on the type of cell, battery, or battery pack being tested.

As noted above, in some embodiments, a testing system of the present disclosure, such as the multi-testing-unit testing system 200 of FIG. 2, may be user-configured to test multiple battery cells and/or multiple battery packs of the same or differing types using the same or differing testing protocols. Those skilled in the art will readily understand the types of differing test protocols such that neither a detailed listing nor detailed recitation of each is necessary for those skilled in the art to appreciate the broad scope of the present disclosure. Suitable software 228 (i.e., machine-executable instructions) for causing the multi-testing-unit testing system 200 to perform its desired functionalities may be stored in the memory 220 of the testing system and executed by the microprocessor(s) 216 of the multi-testing-unit testing system. In some embodiments, the software 228 may also or alternatively be stored on one or more computer-readable hardware (i.e., not signal-borne) storage media (not shown) other than the memory 220 that is part of the testing system 200. For example, such other hardware storage media may be used to provide the software to the testing system from a location (not shown) remote from the testing system 200.

The protocols that a testing system of the present disclosure, such as the testing system 200 of FIG. 2, may implement include, but are not limited to: setting and/or variation of voltage; setting and/or variation of current; setting and/or variation of temperature; setting and/or variation of device pressure, setting and/or variation of ambient pressure, and setting and/or variation of radiation exposure, etc., at one or more differing test stages, including charging stage(s), discharging stage(s), and resting stage(s); among others; and any combination thereof. To the extent not addressed herein, those skilled in the art will readily understand details, features, and implementations of the circuitry, sensors, and other hardware and software needed to execute any one or more of these and/or other protocols, such that a detailed explanation of each need not be provided herein for those skilled in the art to understand the broad scope of the present disclosure. Rather, those skilled in the art will readily appreciate that it is the unique combining of these features, aspects, functionalities, components, etc., into each testing unit, and in some cases testing units and a testing controller, in accordance with the present disclosure that provides benefits, such as the benefits discussed herein.

FIGS. 3A to 3C illustrate an example instantiation 300 (hereinafter, “testing unit 300”) of a testing device/unit made in accordance with the present disclosure, such as the testing device 100 according to FIGS. 1A to 1C or any one of the testing units 204(1) to 204(N) of FIG. 2, among others. In this instantiation, the testing unit 300 is a drawer-access-type testing unit comprising a cabinet 304C and a drawer 304D, with the cabinet and the front 304DF of the drawer forming an enclosure 304, which in this example is explosion and fire resistant, and defining a test chamber 308. FIG. 3A shows the drawer 304D in its closed position, while FIG. 3B shows the drawer in its open position. In this example, the testing unit 300 includes a top handle 312 to allow a user (not shown) to readily transport and handle the testing unit. The top handle 312 may be removable to allow multiple instantiations of the testing unit 300, or other device, to be stacked atop the testing unit.

This instantiation includes a fixture 316 that generally receives a target test device 320, which here is a pouch-type lithium-metal cell. As noted above, lithium-metal cells are prone to forming mossy lithium (e.g., lithium dendrites) on the anodes (not shown) during charging, and charging such cells under pressure can inhibit formation of such mossy lithium and thereby extend the cycle lives of the cells. Consequently, in this case, the testing unit 300 includes a device-pressure applicator 324 (FIG. 3A), which in this case is a variable-pressure applicator as evidenced by a set of springs 324S. In this device-pressure applicator 324, the target test device 320 is sandwiched between lower and upper pressure plates 324LP and 324UP, respectively. In this embodiment, a visual distance-measuring scale 324MS is provided to allow a user to set the amount that the springs 324S are compressed so as to set the pressure the device-pressure applicator 324 applies to the target test device 320. In other embodiments, other means may be used to set the applied pressure, such as using one or more pressure sensors and corresponding circuitry and/or readout display(s), among others. In this embodiment, the device-pressure applicator 324 is fixedly secured to the fixture 316.

As noted, the target test device 320 in this example is a pouch-type lithium-metal cell, which has a pair of positive and negative electrical tabs (not labeled) (electrodes) that are in electrical communication with, respectively, the cathode layers and the anode layers within the cell and that extend from one end of the cell. In this example, the electrical tabs (electrodes) electrically engage with corresponding positive and negative electrical contacts 328P, 328N, respectively, (here, clip-type electrical contacts; see FIG. 3B for both contacts) to electrically connect the target testing device 320 with the testing device management system (not shown, but see, e.g., testing device management system 120 of FIG. 1A). Other embodiments may have another type of electrical contacts, such as pin-type contacts or spring-type contacts, among others. Other embodiments, such as embodiments for testing battery packs, may have one or more additional electrical contacts (not shown) and/or a multi-pin connector, among other things, depending on the functionality built into the target test battery pack.

As best seen in FIGS. 3A and 3B, the fixture 316, the device-pressure applicator 324, and the electrical contacts 328P and 328N are all coupled to the drawer 304D so as to be movable therewith between the drawer's closed position (FIG. 3A) and open position (FIG. 3B). In this example, the drawer 304D includes a bottom enclosure 304BE to which the fixture 316 is secured and that houses various electronics (not shown; e.g., microprocessor, memory, signal-conditioning circuitry, power supply(ies), control circuitry, communications device(s), etc., and any combination thereof; see, e.g., testing device 100 of FIG. 1A for examples of electronics that may be located within the bottom enclosure) that are part of the testing unit 300, which is self-contained.

The example shown also includes an environment-control system, which includes a pair of fans 332F(1) and 33F(2) that control the flow of air into and out of the testing chamber 308. Not illustrated, but which may be contained in the bottom enclosure 304BE of the drawer 304D, is a fan controller that controls the operation of the individual fans 332F(1) and 332F(2). The fan controller may be configured to operate the fans 332F(1) and 332F(2) independently of one another. For example, the fan controller may operate both fans 332F(1) and 332F(2) to be moving air either into the testing chamber or out of the testing chamber or may operate the fans so that one is moving air into the testing chamber and the other is moving air out of the testing chamber, or may shut one fan down while operating the other fan in either direction, among others. Although not shown, one or both fans 332F(1) and 332F(2) may further include one or more heating elements (e.g., resistance-type heating elements) and/or one or more cooling elements (e.g., thermoelectric cooling elements) for a wider range of environmental control. Alternatively, in other embodiments the heating and or cooling elements (not shown) may be located elsewhere within the testing unit 300. Also shown is a temperature sensor 336 (here a thermistor) that during testing can be engaged with the target test device 320 for use in measuring the temperature of the target test device. Although not shown, the testing unit may include other sensors, such as a voltage sensor and a current sensor, which can be contained in circuitry (not shown) that is in electrical communication with the target test device 320.

FIG. 3C illustrates the front face of the drawer front 304DF showing some of the connection ports that this example testing unit 300 has. The connection ports provided are a testing-power-input connector 340, an Ethernet connector 344, and an auxiliary fan-power connector 348. In this instantiation, the testing-power-input connector 340 includes two pairs of positive and negative electrical inputs, specifically, a first and second pairs 340BC and 340BP. In some instantiations, the first pair 340BC may be provided for main charging/discharging current, and the second pair 340BP may be provided for voltage sensing. In some instantiations, the first pair 340BC may be provided for powering testing of the target test device 320 when it is a single battery cell, and the second pair 340BP may be provided for powering testing of the target test device when it is a battery pack. Not shown are separate electrical contacts on the fixture 316 for electrically connecting a battery pack to the testing unit 300 (only the electrical contacts 328P and 328N are shown for the illustrated pouch-type lithium-metal battery cell as the target test device 320). The Ethernet connector 344 allows the testing unit 300 to be communicatively connected to a testing controller (not shown, but see the testing controller 208 of FIG. 2). In other embodiments, other types of communications connector(s) can be used or communications may be effected wirelessly. In this example, the fans 332F(1) and 332F(2) are 12-volt fans, and the backup fan-power connector 348 allows a backup power source to be connected to the fans if the power provided via the testing-power-input connector 340 is not sufficient to power all of the other testing electronics aboard the testing unit 300.

Following is an example technical specification for a specific instantiation of a testing device/unit of the present disclosure, such as any of the testing devices/units 100, 204(1) to 204(N), and 300 discussed above. Those skilled in the art will readily appreciate that this example technical specification is simply an example and nonlimiting in any way. In addition, one skilled in the art will readily be able to design and build actual working instantiations using only this or similar technical specification, guidance of this disclosure, and ordinary skill in the art. It is noted that this example is for a pouch-type lithium-metal battery cell.

### Example Technical Specification

1. Secure fastening of lithium-metal pouch cell
   a. Mechanical fixation
   b. Positional adjustment
   c. Means to enable temperature regulation (heating/cooling)
   d. Means to exert variable or constant force (psi) against pouch-type battery cell
2. Secure and consistent connection to positive and negative electrodes of the battery cell, and optionally to a third gate electrode
3. Microcontroller unit (MCU) with RAM, EEPROM, firmware, digital and analog inputs & outputs
   a. Sensor data collection and transmission
   b. Local (autonomous) control/supervision of cell operating conditions (safety)
4. Sensor package including at least:
   a. voltage (e.g., −5 v to 0 to +5 v)
   b. current (e.g., −32.7 A to 0 to +32.7 A)
   c. temperature (e.g., −40° C. to +300° C.)
   d. pressure (e.g., 14.7 psi to 500 psi)
5. Temperature control
   a. Heating (e.g., liquid, electrical, and/or chemical)
   b. Cooling (passive and/or active)
6. Communications to remote control system (e.g., server)
   a. Periodic transmission of sensor readings
   b. Unscheduled reception of operational testing parameters, limits and profiles from testing controller
   c. Unscheduled reception of operational commands from testing controller (primarily for safety)
7. User Interface
   a. Local to testing device
   b. In addition to remote testing controller
   c. Binary instructions or alternatively, interpreted language via a terminal interface or more elaborate graphical interface
   d. Enters target test device identifying information associated with the sensor data being collected (e.g., serial #, date of manufacture, etc.)
8. Device Interface
   a. Multi-pin connection to voltage, current, temperature, and pressure sensors
   b. Separate connections for battery cell and battery pack power
   c. All solid-state switching for power and safety mechanisms

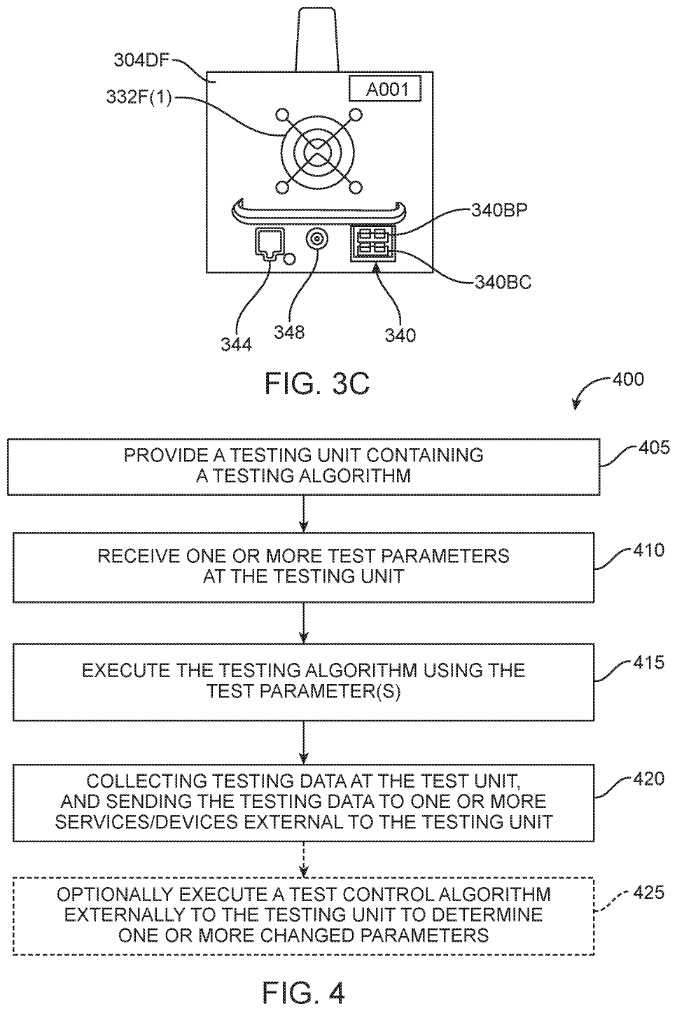

In some aspects, the present disclosure is directed to methods of testing a battery cell or a battery pack composed of one or more battery cells. Referring to FIG. 4, such a method 400 may include, here at block 405, providing a testing unit having a testing algorithm (protocol) local to the testing unit. Examples of testing units that can perform the method 400 include, but are not limited to, the testing device 100 according to FIGS. 1A to 1C, any one of the testing units 204(1) to 204(N) of FIG. 2, or the testing unit 300 of FIGS. 3A to 3C, among others. In such examples, the testing algorithm (protocol) may be stored in a memory aboard the testing unit, such as the memory 116MEM aboard the testing device 100 of FIGS. 1A to 1C. Referring again to FIG. 4, prior to the execution of the testing algorithm or at some other time, at block 410 the testing unit may receive from an external source (e.g., a testing controller the same as or similar to the testing controller 208 of FIG. 2 or another external device as discussed above relative to FIG. 2) one or more testing parameters that influence the manner in which the testing unit executes the testing algorithm. In some cases, each testing parameter may be a changed testing parameter that an external source has determined should replace a corresponding existing testing parameter.

At block 415, after receiving the testing parameter(s) the testing unit executes the testing algorithm using the testing parameter(s). In some embodiments, the method 400 may optionally further include, here at block 420, collecting testing data at the testing unit and sending the testing data to one or more external services and/or devices, such as a central testing controller (see, e.g., testing controller 208 of FIG. 2) or data collection system (e.g., enterprise-based, cloud-based, etc.) (not shown). At optional block 425, the method 400 may optionally further include executing, externally to the testing unit, a test control algorithm that uses the testing data to determine the one or more changed testing parameters, such as the test parameters received by the testing unit in block 410 as discussed above.

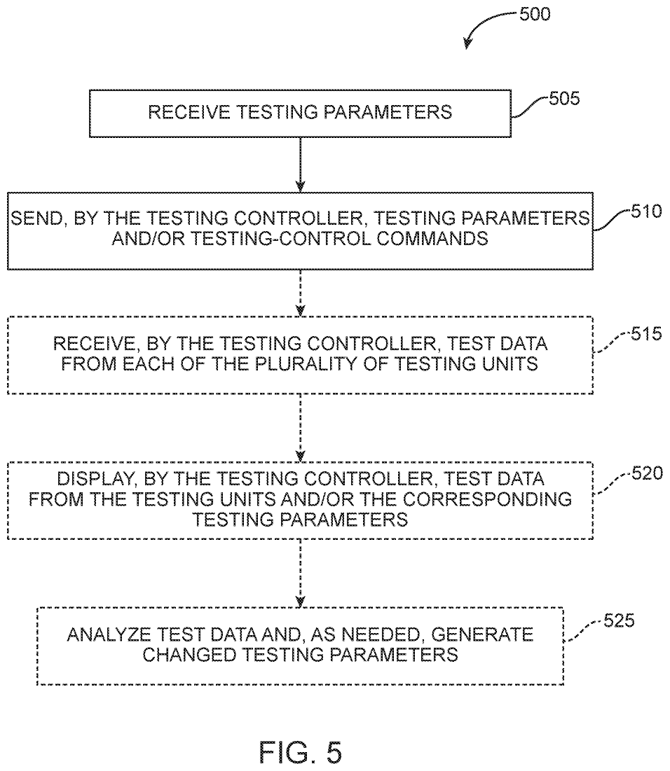

In some aspects, the present disclosure is directed to methods of testing a plurality of battery cells and/or battery packs each containing two or more battery cells. Referring to FIG. 5, an example method 500 of performing such testing may utilize a multi-testing-unit testing system that comprises a plurality of testing units and a central testing controller, with each of the testing units in communication with the central testing controller via a communications link, which may be wired or wireless, depending on the desired configuration. In some embodiments, the multi-testing-unit testing system may be the same as or similar to the multi-testing-unit testing system 200 of FIG. 2, which includes a testing controller 208 and a plurality of testing units 204(1) to 204(N) that communicate with one another over a network 212.

To facilitate control and communication, in some embodiments each testing unit may have a unique address (e.g., media access control (MAC) address, Internet protocol (IP), etc.) or other unique identifier (e.g., custom assigned) that facilitates communications between the central testing controller and each testing unit. In some embodiments, ones of the testing units may share a common identifier so as to group those testing units together if they are to share the same testing protocol and testing parameters. In some embodiments, each testing unit may be assigned its own testing channel. In some embodiments, each testing unit may be a node on a network, such as an Ethernet network, among many others. Fundamentally, those skilled in the art will readily appreciate that the communications link (e.g., network) between the central testing controller and the multiple testing units can be executed in any suitable manner.

In some embodiments, the multi-testing-unit testing method 500 (FIG. 5) may include, at block 505, receiving testing parameters by each of the testing units. In some embodiments, the testing parameters may be received at the testing unit, for example, by way of one more onboard HMI components aboard the testing unit (not shown, but see HMI components 1161-IMI of FIG. 1A). In some embodiments, the testing parameters may be received from one or more offboard sources, for example, the central testing unit or another device, such as a laptop computer, etc., via a direct communications connection or a network communications connection. When a central testing controller provides the testing parameters to each testing unit, the testing controller may itself receive the testing parameters in any of a variety of ways. For example, the central testing controller may receive the testing parameters from a user via one or more HMI components for inputing and/or selecting the testing parameters for one, some, all, groups, etc., of the testing units. As another example, the testing controller may receive the testing parameters via a communications link (e.g., network) from a device (e.g., laptop computer, tablet computer, web server, etc.) external to the testing controller. Those skilled in the art will readily understand that variety of ways that the testing controller can receive the testing parameters for the multiple testing units, while appreciating the importance that it is the standalone nature of each of the testing units that drives the nature and character of the testing parameters for each testing unit and that the provision of such testing parameters allows each testing unit to perform the requisite testing automatedly and without external control.

The testing parameters for each testing unit may include, but not be limited to, charging rate(s), discharging rate(s), charging current(s), charging voltage(s), environmental temperature(s), pressure(s) applied to the target test device during each of one or more testing phases, radiation level(s), etc., and any combination thereof. Those skilled in the art will readily understand the testing parameters that can be received at block 505 by either each testing unit and/or the testing controller. In some cases, the testing parameters may be changed testing parameters received after performing a portion of the overall testing desired to be performed on the relative target test device. In some cases, such as when the central testing controller includes automated testing-analysis software, the changed testing parameters may be determined by such software based on analysis of testing data that the testing controller receives (see optional block 525, below).

At block 510, the central testing controller sends testing parameters and/or testing-control commands to the testing units via the communications link (e.g., network). As noted above, this communication may be effected over a network and/or using any suitable communications protocol(s) dictated by the communications connection(s) between the testing controller and the testing units. In some embodiments, the testing parameters may or may not include changed testing parameters or may only include changed testing parameters, depending on the manner by which initial testing parameters are received by each testing unit. In some embodiments, the testing parameters include differing sets of testing parameters for differing testing units or differing sets of testing units, as the testing plan and the character and nature of the test devices in the test set may dictate. As but one simple example, a set of 20 identical battery packs can be tested, for example, in five groups of four battery packs each, with the battery packs in each of the five groups being subject to the same environmental conditions (e.g., temperature(s), ambient pressures, device pressure) as one another but wherein the environmental conditions vary among the five differing groups. If the testing parameters are not provided by the testing controller, the testing controller may nonetheless provide high-level testing-control commands, such as start testing, stop testing, and emergency shutdown, among others, and/or the like.

At optional block 515, the method 500 may further include receiving, by the testing controller, test data from each of the plurality of testing units. The test data may be received at the central testing controller and may be any test data generated by each of the testing units based on the testing performed by that testing unit based on the testing parameters received at block 505, above. Examples of test data may include, but not be limited to, cycle number, measured temperature(s), measured pressure(s), measured current(s), measured voltage(s), fault indicator(s), and measured radiation, among others, or any combination thereof. At optional block 520, the testing controller may display some or all of the received test data from the testing units, in some cases along with other information, such as information identifying one or more corresponding ones of the test units (e.g., assigned cell/pack serial number, assigned test-unit identifier, etc.), the testing parameters corresponding to the test data, time, and date, among others, or any combination thereof. Those skilled in the art will readily appreciate the type of information that the testing unit may display.

At optional block 525, the testing controller may include test-data-analysis software designed and configured to analyze the test data and, when appropriate, determine that one or more of the testing parameters needs to be changed. In a simple example, the test-data-analysis software may determine that enough testing has been performed using one (e.g., first) set of testing parameters and, in response thereto, substitute-in another (e.g., second) set of testing parameters. For example, the first set of testing parameters may have been set for applying a first set of environmental conditions, while the second set of testing parameters may include testing parameters for applying a second set of environmental conditions different from the first set of environmental conditions. This is merely a single simple example. Those skilled in the art will readily understand how to design and embody test-data-analysis software for any suitable testing scenario without undue experimentation.

In some aspects, the present disclosure is directed to machine-readable hardware storage media containing machine-executable instructions for executing any of the methods disclosed herein. In this disclosure and in the appended claims, the term “machine-readable hardware storage media” excludes storage of instructions on one or more transitory signals, requiring physical hardware, including machine memory of any type, either nonvolatile or volatile, suitable for storing machine-executable instructions and in any suitable combination of memory type and any suitable combination of memory location, such as onboard one or more microprocessors executing the machine-executable instructions, local to such one or more microprocessors, or remote from such one or more microprocessors, and any combination thereof. Those skilled in the art will readily understand how to create the necessary machine-executable instructions for any instantiation of a testing device/unit and/or multi-testing-unit system of the present disclosure based on the functionality embodied in that instantiation such that further explanation is not necessary herein for such skilled artisans to practice the present inventions to their fullest scope.

Benefits of a testing device/unit of the present disclosure include, but are not limited to, in any suitable combination:
standardized battery testing units simplify testing protocols and interfaces;
low cost;
enables standalone or networked testing of batteries/battery packs/cells;
abstracts battery-cell/pack-specific connections to a standardized interface for connection to a network;
supervises testing and provides safety invention when conditions exceed or are predicted to exceed permitted limits;
provides access to testing unit sensors that are monitoring the battery cell/battery pack operation;
provides a safe, secure container to move/test the onboard battery/battery pack/cell in a portable configuration; and
provides a means to attach a test fixture/jig that provides either a constant gap or constant pressure regime to the battery/battery pack/cell.

Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

1. A testing device for testing a target test device composed of one or more battery cells, comprising:
an enclosure designed, configured, and constructed to define a testing chamber that encloses the target test device and to contain or reduce the severity of an explosion of the target test device;
a testing-device management system designed, configured, and constructed to be electrically connected to the target test device, to continually monitor one or more conditions of the target test device during testing, and to stop testing if the battery management system detects that any of the one or more conditions are out of an acceptable range, wherein the testing-device management system includes:
circuitry for electrically interfacing with the target test device;
one or more processors;
memory operatively connected to the one or more processors; and
machine-executable instructions stored in the memory and executable by the one or more processors to control operations of the testing-device management system.

2. The testing device of claim 1, further comprising a fixture designed, configured, and constructed to hold the target test device within the testing chamber.

3. The testing device of claim 1, further comprising at least one communications port in operative communication with the testing-device management system, the at least one communications port designed and configured to provide a connection to an external system that interacts with the testing-device management system.

4. The testing device of claim 1, further comprising a sensor suite that is designed, configured, and implemented to measure voltage and current into and out of the target test device during charging and discharging of the target test device.

5. The testing device of claim 4, wherein the sensor suite further comprises sensors for sensing temperature of and compressive pressure within the target test device.

6. The testing device of claim 1, wherein the unit further includes an environmental control system designed, configured, and controllable so as to manage at least one environmental condition within the testing chamber.

7. The testing device of claim 6, wherein the environmental condition is temperature during testing, and the testing-device management system further includes circuitry for controlling the environmental control system so as to control the temperature within the testing chamber during testing.

8. The testing device of claim 7, wherein the environmental control system includes a heater.

9. The testing device of claim 7, wherein the environmental control system includes a heater and a cooler.

10. The testing device of claim 9, wherein the cooler comprises a thermoelectric cooler.

11. The testing device of claim 1, wherein the electrical connection system includes quick-connect electrical connectors designed and configured to connect to electrodes of the target test device.

12. The testing device of claim 1, wherein the fixture includes a pressure-module receiver for removably fixedly securing a pressure module in the testing chamber.

13. The testing device of claim 12, further comprising a constant-pressure pressure module and a fixed-gap pressure module, wherein each of the constant-pressure pressure module and the fixed-gap pressure module is designed and configured to be alternatingly fixedly secured to the pressure-module receiver.

14. The testing device of claim 1, wherein the testing device is portable and includes a handle designed and configured to allow a user to grasp the handle for moving the testing device.

15. The testing device of claim 1, wherein the testing device further comprises a cabinet and a drawer movable relative to the cabinet so as to close and open the enclosure.

16. The testing device of claim 15, wherein, when the drawer is closed, the drawer and the cabinet form the enclosure and define the testing chamber.

17. The testing device of claim 15, wherein the fixture is secured to the drawer so as to be movable with the drawer.

18. The testing device of claim 15, wherein the drawer includes an electronics compartment that contains the one or more processors and the memory.

19. The testing device of claim 1, wherein the testing device management system is further designed, configured, and constructed to:
control testing of the target test device based on testing parameters; and
collect, from the testing, test data;
receive from an external source one or more changed testing parameters; and
conduct testing of the target test device using the one or more changed testing parameters.

20. The testing device of claim 19, wherein the testing device management system is yet further designed, configured, and constructed to:
output the test data to an external device;
receive from an external source one or more changed testing parameters; and
conduct testing of the target test device using the one or more changed testing parameters.

21. The testing device of claim 20, further comprising at least one communications port that includes a wireless radio for establishing a wireless link with a testing controller for outputting the test data and receiving the one or more changed testing parameters.

22. The testing device of claim 15, further comprising at least one communications port that includes a wired data connection receptacle for establishing a wired link with a testing controller for outputting the test data and receiving the one or more changed testing parameters.

23. The testing device of claim 1, wherein the fixture is designed, configured, and constructed to fixedly hold any one of a plurality of differingly sized and/or configured target test devices as the target test device.

24. The testing device of claim 23, wherein the circuitry is designed, configured, and constructed to adapt, serially, to all of the plurality of differingly sized and/or configured target tested devices as the target test device.

25. The testing device of claim 1, wherein the fixture is designed and configured to be engaged by any one of a plurality of differing target-test-device adapter modules each designed, configured, and constructed to fixedly hold any one of a plurality of differingly sized and/or configured target test devices as the target test device.

26. The testing device of claim 25, wherein one of the differing target-test-device adapter modules is engaged with the fixture.

27. The testing device of claim 1, wherein the machine-executable instructions includes machine-executable instructions for providing the testing device with a user interface for controlling operation of the testing device.

28. The testing device of claim 27, wherein the user interface is accessible via the at least one communications port.

29. A testing system, comprising:
a testing controller; and
a plurality of testing devices of claim 1 in operative communication with the test controller via a communications link.

30. The testing system of claim 29, wherein the communications link includes a wireless link operatively connecting the testing devices to the test controller.

31. The testing system of claim 29, wherein the communications link includes a wired link operatively connecting the testing devices to the test controller.

32. The testing system of claim 29, wherein:
the machine-executable instructions of each testing device includes machine-executable instructions for:
controlling testing of the target test device based on testing parameters;
collecting and outputting from the testing unit test data regarding the target test device;
receiving from an external source one or more changed testing parameters; and
conducting testing of the target test device using the one or more changed testing parameters; and
the testing controller includes:
one or more second processors;
second memory operatively connected to the one or more second processors; and
machine-executable instructions stored in the second memory and executable by the one or more second processors, the machine-executable instructions configured for:
receiving the test data from each of the testing devices;
executing a control algorithm that uses the test data to determine the one or more changed testing parameters; and
communicating the one or more changed testing parameters to one or more pertinent ones of the testing devices via the communications link.

33. A method of testing a target test device composed of one or more battery cells, the method comprising:
executing, by a testing unit, a testing algorithm to conduct testing on the target test device based on a plurality of testing parameters;
receiving from an external source one or more changed testing parameters; and
executing, by the testing unit, the testing algorithm to conduct testing on the battery cell or battery pack using the one or more changed testing parameters.

34. The method of claim 33, further comprising collecting, by the test unit, test data during the testing, and transmitting the test data to a central controller.

35. The method of claim 34, further comprising receiving the test data, executing a test control algorithm that uses the test data to determine the one or more changed testing parameters, and transmitting the one or more changed parameters to the testing unit.

36. A method of performing testing on a plurality of target test devices, wherein each of the target test devices is tested in a corresponding self-contained testing unit operatively connected by a communications link to a testing controller, the method comprising:
determining testing parameters for each of the self-contained testing units; and
sending the testing parameters to the self-contained testing units via the communications link.

37. The method of claim 36, wherein the testing parameters include different sets of testing parameters for differing ones of the self-contained testing units.

38. The method of claim 37, further comprising receiving test data from each of the plurality of self-contained testing units, executing a test control algorithm that uses the test data to determine the one or more changed testing parameters, and transmitting the one or more changed parameters to at least a corresponding one of the self-contained testing units.

39. One or more machine-readable hardware storage media containing machine-executable instructions for performing the method of claim 33.
